(19) United States
(12) Patent Application Publication
(10) Pub. No.: US 2025/0337220 A1
(43) Pub. Date: Oct. 30, 2025

(54) VERTICAL CAVITY SURFACE EMITTING LASER ELEMENT

(71) Applicant: NICHIA CORPORATION, Anan-shi (JP)

(72) Inventors: Kohei INOUE, Anan-shi (JP); Kenichi TERAO, Tokushima-shi (JP); Kazutaka TSUKAYAMA, Tokushima-shi (JP); Takashi OHARA, Tokushima-shi (JP); Ryoma SHIMAZU, Anan-shi (JP)

(21) Appl. No.: 19/189,126

(22) Filed: Apr. 24, 2025

(30) Foreign Application Priority Data
Apr. 26, 2024 (JP) 2024-072447

(51) Int. Cl. H01S 5/183; H01S 5/042; H01S 5/30

(52) U.S. Cl. CPC H01S 5/18352; H01S 5/0421; H01S 5/18347; H01S 5/18377; H01S 5/3013; H01S 5/3077

(57) ABSTRACT

A vertical cavity surface emitting laser element includes first and second light reflecting layers, first, second and third semiconductor layer portions, an active layer, and first and second electrodes. The first semiconductor layer portion is disposed on the first light reflecting layer and contains a first impurity of a first conductivity type. The second semiconductor layer portion contains a second impurity of a second conductivity type. The third semiconductor layer portion is disposed on the second semiconductor layer portion, contains a third impurity of the first conductivity type at a higher concentration than a concentration of the first impurity, and has a thickness of 10 nm or more and less than 100 nm. The second light reflecting layer is disposed on the third semiconductor layer portion. The first electrode is electrically connected to the first semiconductor layer portion. The second electrode is in contact with the third semiconductor layer portion.

### CROSS-REFERENCE TO RELATED APPLICATION

This application claims priority to Japanese Patent Application No. 2024-072447 filed on Apr. 26, 2024, the disclosure of which is hereby incorporated herein by reference in its entirety.

### BACKGROUND

### Technical Field

The present disclosure relates to a vertical cavity surface emitting laser element.

### Background Art

In recent years, semiconductor laser elements have been used in various fields. A vertical cavity surface emitting laser (VCSEL) element has attracted attention as a semiconductor laser element having relatively low power consumption.

Japanese Patent Application Publication No. 2021-036553 discloses a nitride semiconductor light-emitting element including, on a p-type GaN layer, a tunnel junction layer including a p⁺⁺-type GaN layer and an n⁺⁺-type GaN layer, and an n-type GaN current diffusion layer. Japanese Patent Application Publication No. 2021-036553 discloses an example of a surface emitting laser in which the n⁺⁺-type GaN layer is 15 nm thick and the n-type GaN current diffusion layer is approximately 350 nm thick.

### SUMMARY

Improvement in drive time of a vertical cavity surface emitting laser element is needed.

An object of an embodiment of the present disclosure is to provide a vertical cavity surface emitting laser element with an improved drive time.

A vertical cavity surface emitting laser element includes a first light reflecting layer, a first semiconductor layer portion, a second semiconductor layer portion, an active layer, a third semiconductor layer portion, a second light reflecting layer, a first electrode, and a second electrode. The first semiconductor layer portion is disposed on the first light reflecting layer and contains a first impurity of a first conductivity type. The second semiconductor layer portion contains a second impurity of a second conductivity type. The active layer is disposed between the first semiconductor layer portion and the second semiconductor layer portion. The third semiconductor layer portion is disposed on the second semiconductor layer portion, contains a third impurity of the first conductivity type at a higher concentration than a concentration of the first impurity in the first semiconductor layer portion, and has a thickness of 10 nm or more and less than 100 nm. The second light reflecting layer is disposed on the third semiconductor layer portion. The first electrode is electrically connected to the first semiconductor layer portion. The second electrode is in contact with the third semiconductor layer portion.

According to an embodiment of the present disclosure, a vertical cavity surface emitting laser element with an improved drive time can be provided.

### BRIEF DESCRIPTION OF DRAWINGS

FIG. 1 is a schematic top view of a vertical cavity surface emitting laser element according to a first embodiment.

FIG. 2 is a schematic cross-sectional view taken along the line II-II in FIG. 1.

FIG. 3 is a schematic enlarged view of the vicinity of a second semiconductor layer portion in FIG. 2.

FIG. 4 is a schematic cross-sectional view of a vertical cavity surface emitting laser element according to a second embodiment.

FIG. 5 is a schematic enlarged view of the vicinity of a second semiconductor layer portion.

FIG. 6 is a schematic cross-sectional view of a vertical cavity surface emitting laser element according to a third embodiment.

FIG. 7 is a schematic plan view of a vertical cavity surface emitting laser array of a fourth embodiment.

FIG. 8A is a graph showing I-L characteristics of vertical cavity surface emitting laser elements of first and second examples and a first reference example.

FIG. 8B is a graph showing I-L characteristics of vertical cavity surface emitting laser elements of a third example and a second reference example.

FIG. 9A is a graph showing lifespan characteristics of the vertical cavity surface emitting laser elements of the first and second examples and the first reference example.

FIG. 9B is a graph showing lifespan characteristics of the vertical cavity surface emitting laser elements of the third example and the second reference example.

### DETAILED DESCRIPTION

Some embodiments of the present disclosure are described below in detail. However, the following embodiments exemplify a vertical cavity surface emitting laser element and a manufacturing method thereof for embodying the technical concept of the present disclosure, and the present disclosure is not limited to the vertical cavity surface emitting laser element and the manufacturing method thereof to be described below.

### First Embodiment

### Vertical Cavity Surface Emitting Laser Element L1

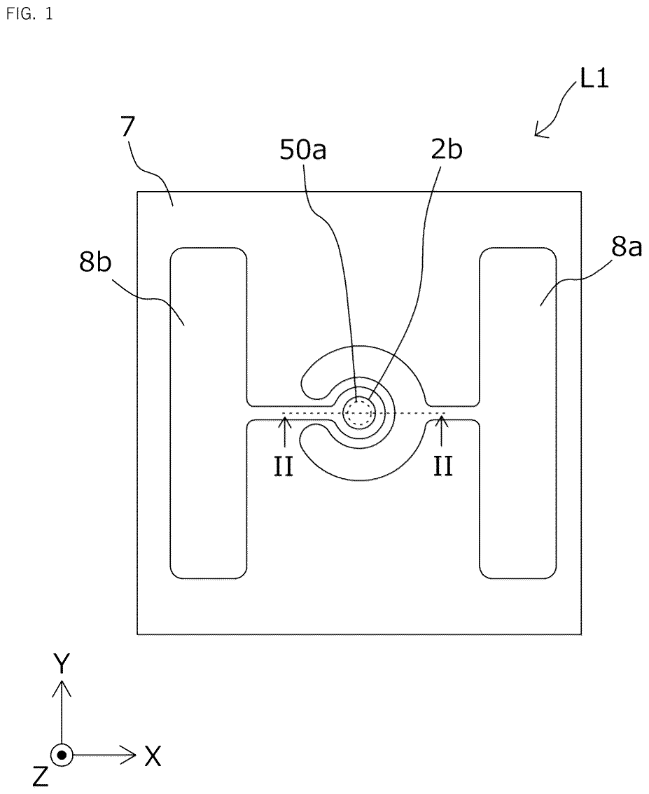

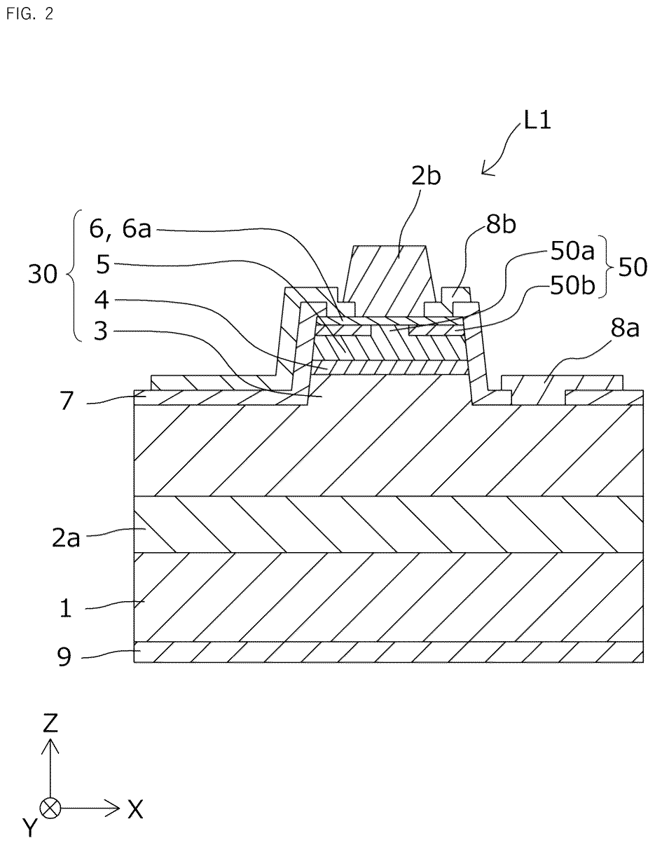

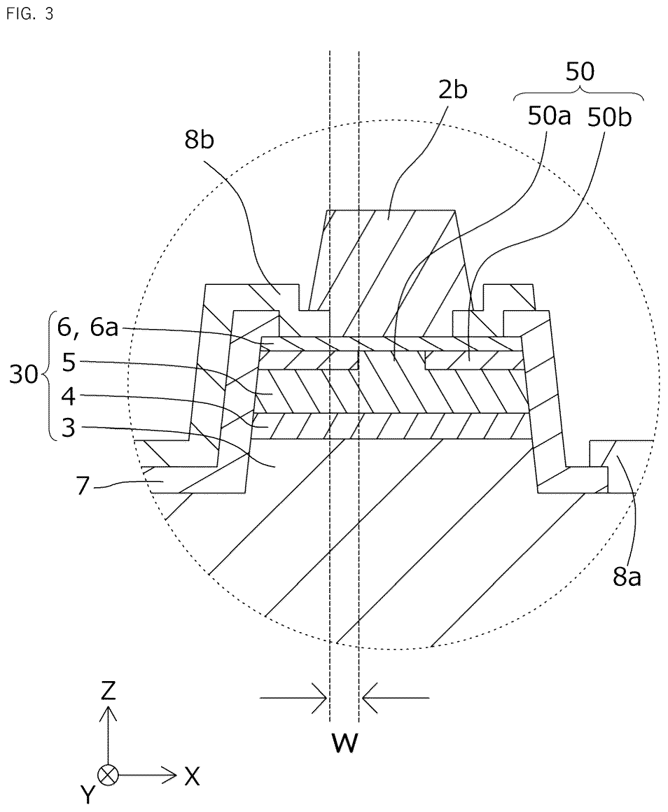

The vertical cavity surface emitting laser element L1 (hereinafter, referred to as a VCSEL element L1) of a first embodiment is described with reference to FIGS. 1 to 3. FIG. 1 is a schematic top view of the VCSEL element L1 of the first embodiment. FIG. 2 is a schematic cross-sectional view taken along the line II-II in FIG. 1. FIG. 3 is a schematic enlarged view of the vicinity of a p-side semiconductor layer portion in FIG. 2.

In this specification, a thickness direction refers to a direction in which semiconductor layers are layered. In the drawings, the thickness direction is represented by a z-axis. A width in the thickness direction is simply referred to as a thickness. Directions in a plane orthogonal to the thickness direction are represented by an x-axis and a y-axis.

As illustrated in FIGS. 1 and 2, the VCSEL element L1 of the first embodiment includes a first light reflecting layer 2a, a first semiconductor layer portion 3 disposed on the first light reflecting layer 2a and containing a first conductivity-type first impurity, a second semiconductor layer portion 5 containing a second conductivity-type second impurity, an active layer 4 disposed between the first semiconductor layer portion 3 and the second semiconductor layer portion 5, a third semiconductor layer portion 6 disposed on the second semiconductor layer portion 5, containing a first conductivity-type third impurity at a higher concentration than that of the first impurity, and having a thickness of 10 nm or more and less than 100 nm, a second light reflecting layer 2b disposed on the third semiconductor layer portion 6, a first electrode 8a electrically connected to the first semiconductor layer portion 3, and a second electrode 8b in contact with the third semiconductor layer portion 6.

With this structure, the VCSEL element L1 can have an improved drive time.

In the VCSEL element L1, a semiconductor layered body 30 is disposed between the first light reflecting layer 2a and the second light reflecting layer 2b to form a resonator. When current is injected into the VCSEL element L1, light is amplified by the resonator and the VCSEL element L1 emits laser light. In the example illustrated in FIG. 2, the laser light passes through the first semiconductor layer portion 3, a substrate 1, and an antireflection coating 9 and is extracted. A resonator length, that is, a distance between the first light reflecting layer 2a and the second light reflecting layer 2b is set to a thickness corresponding to an integer multiple of λ/(2×n_{eq}), where λ is an oscillation wavelength of the laser light and n_{eq} is an equivalent refractive index of a mode in an optical waveguide. The resonator length may be, for example, in a range of 2 times to 20 times or 2 times to 15 times λ/(2×n_{eq}).

The semiconductor layered body 30 includes the first semiconductor layer portion 3, the active layer 4, the second semiconductor layer portion 5, and the third semiconductor layer portion 6. The semiconductor layer portions and the active layer 4 can be formed by chemical vapor deposition or physical vapor deposition. The chemical vapor deposition may be, for example, metal organic chemical vapor deposition. The physical vapor deposition may be molecular beam epitaxy or sputtering. The configurations thereof are described below.

In the following description, the first conductivity type is mainly n-type and the second conductivity type is mainly p-type; however, the first conductivity type may be p-type and the second conductivity type may be n-type. In this case, the following descriptions of n-type and p-type may be interchanged.

In this specification, an undoped semiconductor layer means a semiconductor layer that is not intentionally doped with an impurity or a semiconductor layer having a detection limit value or less of secondary ion mass spectrometry (SIMS). For example, when Si (silicon) is included as an n-type impurity, the n-type impurity concentration may be 1×10¹⁶ cm⁻³ or less. For example, when Ge (germanium) is included as an n-type impurity, the n-type impurity concentration may be 1×10¹⁷ cm⁻³ or less.

### First Semiconductor Layer Portion 3

The first semiconductor layer portion 3 is disposed on the first light reflecting layer 2a to be described below. The first semiconductor layer portion 3 has a mesa structure, and each semiconductor layer portion to be described below is disposed on the mesa structure. The first semiconductor layer portion 3 may be, for example, a group III-V semiconductor, preferably a nitride semiconductor. The first semiconductor layer portion 3 may include, for example, AlGaN, GaN, or InGaN.

The first semiconductor layer portion 3 includes at least one first conductivity-type semiconductor layer including the first conductivity-type first impurity. The first conductivity type is one of n-type and p-type. The first impurity may be, for example, any one of Si, Ge, and Mg (magnesium). When the first conductivity type is n-type, the first impurity may be Si or Ge. The concentration of the first impurity may be, for example, in a range of 1×10¹⁸ cm⁻³ to 1×10²⁰ cm⁻³ or in a range of 1×10¹⁸ cm⁻³ to 7×10¹⁹ cm⁻³. Note that the first semiconductor layer portion 3 may include an undoped semiconductor layer.

The impurity concentration can be analyzed by SIMS. Note that the impurity concentration in a minute region to which SIMS is hardly applied can be analyzed by a three-dimensional atom probe.

### Active Layer 4

The active layer 4 is disposed between the first semiconductor layer portion 3 and the second semiconductor layer portion 5 to be described below. In FIG. 2, the active layer 4 is disposed on the mesa structure. The active layer 4 may have a quantum well structure, which may be a single quantum well structure or a multiple quantum well structure. The active layer 4 can emit, for example, light having peak wavelengths in a range of 360 nm to 700 nm, in a range of 360 nm to 570 nm, or in a range of 375 nm to 540 nm. The active layer 4 can emit light of, for example, ultraviolet to violet wavelengths (that is, 360 nm or more and less than 420 nm), blue wavelengths (that is, 420 nm or more and less than 495 nm), green wavelengths (that is, in a range of 495 nm to 570 nm), or red wavelengths (that is, more than 570 nm and 700 nm or less). The active layer 4 may be, for example, a group III-V semiconductor, preferably a nitride semiconductor. The well layer may be, for example, GaN or InGaN. A barrier layer may be, for example, AlGaN or GaN. The active layer 4 preferably has a multiple quantum well structure. In that case, light is efficiently amplified. Preferably, at least a part of the well layer is disposed at an antinode portion of a standing wave of light formed by the resonator. Thus, light easily obtains gain and is efficiently amplified. Second Semiconductor Layer Portion 5

The second semiconductor layer portion 5 is disposed on the active layer 4. The second semiconductor layer portion 5 may be, for example, a group III-V semiconductor, preferably a nitride semiconductor. The second semiconductor layer portion 5 may include, for example, AlGaN, GaN, or InGaN.

The second semiconductor layer portion 5 includes at least one second conductivity-type semiconductor layer including the second conductivity-type second impurity. The second conductivity type is n-type or p-type, which is a conductivity type different from the first conductivity type. The second impurity may be, for example, any one of Si, Ge, and Mg. When the second conductivity type is p-type, the second impurity is preferably Mg. The concentration of the second impurity may be, for example, in a range of 1×10¹⁸ cm⁻³ to 1×10²¹ cm⁻³ or in a range of 5×10¹⁸ cm⁻³ to 5×10²⁰ cm⁻³. The second semiconductor layer portion 5 may include an undoped semiconductor layer.

The thickness of the second semiconductor layer portion 5 may be, for example, in a range of 50 nm to 2000 nm. When the second conductivity type is p-type, the thickness of the second semiconductor layer portion 5 is preferably in a range of 50 nm to 200 nm, for example. The light absorption of a p-type semiconductor layer tends to be larger than that of an n-type semiconductor layer, but the light absorption can be reduced in the above range.

The surface of the second semiconductor layer portion 5 is preferably flat. This makes it easy to form the third semiconductor layer portion 6 flat. The arithmetic average height Sa of the surface of the second semiconductor layer portion 5 may be, for example, in a range of 0.1 nm to 2 nm or in a range of 0.1 nm to 1 nm.

### Current Constriction Structure 50

As illustrated in FIGS. 2 and 3, the second semiconductor layer portion 5 may include a current constriction structure 50. The current constriction structure 50 includes a current injection region 50a and a non-current injection region 50b surrounding the periphery of the current injection region 50a in a top view. Thus, current can be efficiently injected into the active layer 4. The current injection region 50a corresponds to the circular dotted line illustrated in FIG. 1.

### Current Injection Region 50a

The width of the current injection region 50a in a top view may be, for example, in a range of 2 times to 20 times the length of the oscillation wavelength. In addition, the width of the current injection region in top view may be preferably in a range of 2 times to 10 times, more preferably in a range of 5 times to 8 times the length of the oscillation wavelength. This allows oscillation in a fundamental mode. The width (diameter or length of a major axis) of the current injection region 50a may be, for example, in a range of 1 um to 15 um, in a range of 1 um to 10 um, or in a range of 1 um to 6 um. The width (diameter or length of the major axis) of the current injection region 50a may be preferably in a range of 2 um to 5 um. With this structure, uniform current injection is facilitated. The shape of the current injection region 50a is preferably circular in a top view. Thus, the shape of a far field pattern of laser light extracted from the VCSEL element L1 can be made circular. When an optical element is disposed at a downstream of the VCSEL element L1, beam shaping by the optical element is facilitated.

### Non-current Injection Region 50b

The non-current injection region 50b surrounds the current injection region 50a in the top view. The non-current injection region 50b may be, for example, a gallium-containing oxide layer provided at a part of the surface of the second semiconductor layer portion 5. With this structure, the electric resistance of the non-current injection region 50b can be increased, and current can be efficiently injected into the current injection region 50a through the third semiconductor layer portion 6. When the second semiconductor layer portion 5 is a nitride semiconductor, the oxide layer may be gallium oxide, gallium oxynitride, or a mixture thereof. The thickness of the non-current injection region 50b may be in a range of 0.1 nm to 10 nm or in a range of 0.5 nm to 5 nm. The oxide layer of the non-current injection region 50b may include aluminum at least in part thereof. Aluminum may be supplied from the material of the second semiconductor layer portion 5, or may be supplied from a transfer tool, a support substrate, or the like during a manufacturing process. When the non-current injection region 50b includes aluminum, the insulating property of the non-current injection region 50b can be increased. This is because oxidation of the non-current injection region 50b can be facilitated by aluminum included in the non-current injection region 50b. Because the oxide layer is a minute region, the oxide layer is desirably analyzed using a (scanning) transmission electron microscope ((S) TEM) and an energy dispersive X-ray spectroscopy (EDS) in combination.

The non-current injection region 50b may be obtained by heat treatment in an oxygen atmosphere. The oxygen atmosphere may be an air atmosphere, but is preferably an atmosphere in which the proportion of oxygen is higher than the oxygen concentration in the air. The oxygen content may be, for example, 20% or more, 50% or more, or 80% or more. This allows for facilitating formation of the oxide layer on the non-current injection region 50b. The heat treatment may be performed, for example, at a temperature of 600° C. or higher or 700° C. or higher. When the heat treatment is performed, a portion corresponding to the current injection region 50a is masked so that the contact with oxygen is reduced.

As described above, a surface of the second semiconductor layer portion 5 is preferably flat. Accordingly, the height difference between the current injection region 50a and the non-current injection region 50b is preferably close to 0 nm. For example, the height difference between the surface of the current injection region 50a and the surface of the non-current injection region 50b may be 1.5 nm or less or 1 nm or less. This height difference may be obtained by(S) TEM analysis of a cross section including the boundary between the current injection region 50a and the non-current injection region 50b.

The non-current injection region 50b is not limited to a gallium-containing oxide layer. The non-current injection region 50b may be, for example, an insulating layer formed by ion implantation, or an insulating layer in which oxide is formed after etching a region other than the current injection region. Alternatively, the non-current injection region 50b may be a semiconductor layer in which a nitride semiconductor having a higher band gap energy than the nitride semiconductor of the current injection region 50a is regrown to relatively increase electric resistance after a region other than the current injection region 50a is etched. In this case, the current injection region 50a may have a protruding shape. The height of the protruding shape may be, for example, in a range of 10 nm to 1 μm.

### Third Semiconductor Layer Portion 6

The third semiconductor layer portion 6 is disposed on the second semiconductor layer portion 5. The third semiconductor layer portion 6 may be, for example, a group III-V semiconductor, preferably a nitride semiconductor. The third semiconductor layer portion 6 may include, for example, AlGaN, GaN, or InGaN, and preferably includes AlGaN or GaN. With this structure, the absorption of light by the third semiconductor layer portion 6 can be reduced and the loss in the resonator can be reduced.

The third semiconductor layer portion 6 includes the first conductivity-type third impurity. The concentration of the third impurity is higher than the concentration of the first impurity. With this structure, as compared with a case in which the concentration of the third impurity is equal to or lower than the concentration of the first impurity, the width of a depletion layer formed by the tunnel junction formed between the second semiconductor layer portion 5 and the third semiconductor layer portion 6 is narrower, so that current injection can be efficiently performed. The third impurity may be, for example, any one of Si, Ge, and Mg. When the first conductivity type is n-type, the third impurity may be Si or Ge and is preferably Ge. By selecting Ge as the third impurity, even if the concentration of the third impurity is increased, the flatness of the surface of the third semiconductor layer portion 6 is less likely to deteriorate, so that the second light reflecting layer 2b can be stably formed. This is because the difference in ionic radius between Ge and Ga is smaller than the difference in ionic radius between Si and Ga, and thus influence of strain is thought to be smaller in the case of containing Ge than in the case of containing Si even if the concentrations of Ge and Si are the same. The concentration of the third impurity is preferably in a range of 2×10¹⁹ cm⁻³ to 1×10²² cm⁻³, in a range of 1×10²⁰ cm⁻³ to 1×10²² cm⁻³, or in a range of 2×10²⁰ cm⁻³ to 1×10²¹ cm⁻³. Thus, the width of the depletion layer formed by the tunnel junction can be narrowed and a forward voltage can be reduced.

The thickness of the third semiconductor layer portion 6 is 10 nm or more and less than 100 nm. With this structure, the lifespan characteristics of the VCSEL element L1 can be improved. The VCSEL element L1 can be continuously driven for 500 hours or more, for example. The thickness of the third semiconductor layer portion 6 may be preferably 10 nm or more and less than 60 nm or in a range of 10 nm to 30 nm. With the impurity concentration of the third semiconductor layer portion 6 higher than the impurity concentration of the first semiconductor layer portion 3, light absorption is likely to occur, but the absorption loss is reduced by reducing the thickness of the third semiconductor layer portion 6 to be a relatively small thickness such as in the above range. Thus, a threshold current density can be reduced. Thus, the lifespan characteristics of the VCSEL element L1 can be further improved. The VCSEL element L1 can be continuously driven for, for example, 600 hours or more, 800 hours or more, or 1000 hours or more.

When the thickness of the third semiconductor layer portion 6 is 10 nm or more, the third semiconductor layer portion 6 is likely to have a flat surface, and the loss due to scattering at an interface between the third semiconductor layer portion 6 and the second light reflecting layer 2b can be reduced. In addition, when the thickness of the third semiconductor layer portion 6 is less than 100 nm, the loss due to light absorption can be reduced as compared with when the thickness of the third semiconductor layer portion 6 is 100 nm or more. From the viewpoint of reducing the light absorption in the third semiconductor layer portion 6, the thickness of the third semiconductor layer portion is preferably thin.

The third semiconductor layer portion 6 is preferably located at or near a node of a standing wave of light formed by the resonator. In that case, the light absorption in the third semiconductor layer portion 6 having a relatively high impurity concentration is reduced, and laser light is efficiently obtained.

In addition, with the thickness of the third semiconductor layer portion 6 less than 100 nm or less than 60 nm, the resonator length is easily adjusted as compared with a case of employing a semiconductor layer greater than these thicknesses. That is, even if an error of several percent occurs in the thickness in the manufacturing process, by setting the absolute value of the thickness of the third semiconductor layer portion 6 in the above range, the deviation between the thickness of the third semiconductor layer portion 6 and the designed value of the resonator length is reduced, and the positional deviation between the third semiconductor layer portion 6 and the node of the standing wave is reduced. The positional deviation between the third semiconductor layer portion 6 and the node of the standing wave may be in a range of 0.2% to 2%, in a range of 0.2% to 1%, or in a range of 0.4% to 1% with respect to the length of one wavelength. The thickness of the third semiconductor layer portion 6 is preferably 30 nm or less. As described above, even if an error of several percent occurs in the manufacturing process, deviation of the thickness of the third semiconductor layer portion 6 from its designed value is relatively small because the designed value is relatively small. Accordingly, as compared with when the thickness of the third semiconductor layer portion 6 is larger than 30 nm, the positional deviation between the third semiconductor layer portion 6 and the node of the standing wave can be further reduced.

The third semiconductor layer portion 6 is preferably single crystal. In that case, the lifespan characteristics are improved as compared with when the third semiconductor layer portion 6 is polycrystal. This is presumably because the loss and the resistance due to a grain boundary are reduced by the single crystal as compared with the polycrystal. Crystallinity can be analyzed by using(S) TEM and electron diffraction in combination. The single crystal of the third semiconductor layer portion 6 can be obtained by epitaxial growth.

As described above, the VCSEL element L1 can emit light with a peak wavelength in a range of 360 nm to 700 nm. When such a VCSEL element L1 includes the third semiconductor layer portion 6, the lifespan characteristics can be significantly improved. This is presumably because the third semiconductor layer portion 6 has few grain boundaries and high crystal quality as compared with a light-transmissive electrode made of oxide and often used in these wavelength bands.

The surface of the third semiconductor layer portion 6 is preferably flat. In that case, the second electrode 8b formed on the third semiconductor layer portion 6 can be disposed on a flat surface. Accordingly, current concentration caused by bending or the like of the second electrode 8b can be avoided. The arithmetic mean height Sa of the surface of the third semiconductor layer portion 6 may be, for example, in a range of 0.1 nm to 2 nm, preferably in a range of 0.1 nm to 1 nm. The Sa can be calculated based on a measurement result obtained by measuring the irregularity of the surface of the third semiconductor layer portion 6 by using an atomic force microscope (AFM). Specifically, after the second light reflecting layer 2b is removed, the exposed surface of the third semiconductor layer portion 6 is analyzed by A FM. The second light reflecting layer 2b may be removed by wet etching. After the second electrode 8b is also removed in a similar manner, the surface of the third semiconductor layer portion 6 may be analyzed by AFM. Sa of a part of the surface of the third semiconductor layer portion 6 immediately above the current injection region 50a is preferably in a range of 0.1 nm to 1 nm. In addition, Sa of a part of the surface of the third semiconductor layer portion 6 immediately above the non-current injection region 50b is in a range of 0.1 nm to 1 nm. With the surface of the third semiconductor layer portion 6 immediately above the current injection region 50a and the surface of the third semiconductor layer portion 6 immediately above the non-current injection region 50b having substantially the same flatness, the second light reflecting layer 2b formed thereon can be formed flat. Thus, the diffraction loss can be reduced.

### First Layer 6a

In the first embodiment, as illustrated in FIG. 2, the third semiconductor layer portion is composed of the first layer 6a in contact with the second semiconductor layer portion and the second electrode 8b. The thickness of the first layer 6a may be 10 nm or more and less than 100 nm, preferably 10 nm or more and less than 30 nm. In that case, the lifespan characteristics of the VCSEL element L1 are improved. Specifically, the VCSEL element L1 can be continuously driven for 1000 hours or more.

### First Light Reflecting Layer 2a

The first light reflecting layer 2a is provided under the first semiconductor layer portion 3. The first light reflecting layer 2a is a multilayer film in which two or more kinds of materials having different refractive indexes are layered. The first light reflecting layer 2a may be a semiconductor multilayer film. In that case, the first light reflecting layer 2a can be formed in a series of growth processes for forming the semiconductor layer on the substrate 1, and the thicknesses of the respective layers are easily controlled. The number of periods of the multilayer film may be in a range of 1 to 100, preferably in a range of 10 to 90, more preferably in a range of 20 to 70. The total thickness of the first light reflecting layer 2a may be appropriately set in accordance with desired reflectance and reflection band. The thickness of each layer of the multilayer film is λ/(4×n). λ is the oscillation wavelength of the VCSEL element L1, and n is the refractive index of a corresponding layer. For example, when the multilayer film is made of AlInN/GaN in a VCSEL element having an oscillation wavelength λ of 450 nm, the thickness of each layer may be in a range of 40 nm to 70 nm. The total thickness of the first light reflecting layer 2a may be, for example, in a range of 0.05 μm to 10 μm, in a range of 0.08 μm to 10 μm, or in a range of 0.1 μm to 8 μm. Thus, optical output can be increased while improving the reflectance of the multilayer film. The size and shape of the first light reflecting layer 2a in top view can be appropriately set as long as the first light reflecting layer 2a covers the resonator.

The first light reflecting layer 2a may be a group III-V semiconductor, preferably a nitride semiconductor. Specifically, examples of the nitride semiconductor include AlN, InN, GaN, AlGaN, InGaN, AlInN, and AlInGaN. In particular, a combination of GaN and AlInN, which lattice-matches with GaN, is preferable.

The first light reflecting layer 2a may be a dielectric multilayer film. In this case, the substrate 1 may be removed after the semiconductor layered body 30 is formed, and the dielectric multilayer film may be formed on the surface exposed from the semiconductor layered body 30 by removing the substrate 1. The dielectric multilayer film may be, for example, oxide, nitride, or fluoride of Si, Mg, aluminum (Al), hafnium (Hf), niobium (Nb), zirconium (Zr), scandium (Sc), tantalum (Ta), gallium (Ga), zinc (Zn), yttrium (Y), boron (B), titanium (Ti), or the like. The first light reflecting layer 2a may be, for example, a dielectric multilayer film in which two kinds selected from SiO₂, Nb₂O₃, Ta₂O₅, and Al₂O₃ are alternately repeated. The combination of dielectrics may be SiO₂/Nb₂O₃, SiO₂/Ta₂O₅, or SiO₂/Al₂O₃.

### Second Light Reflecting Layer 2b

The second light reflecting layer 2b is disposed on the third semiconductor layer portion 6. The second light reflecting layer 2b is a multilayer film in which two or more kinds of materials having different refractive indexes are layered. The second light reflecting layer 2b may be a semiconductor multilayer film or a dielectric multilayer film. The second light reflecting layer 2b is preferably a dielectric multilayer film. Thus, a desired reflectance is easily obtained by arbitrarily setting the difference between the refractive indexes of the materials constituting the second light reflecting layer 2b. The thickness of each layer of the multilayer film may be λ/(4×n) similarly to the first light reflecting layer 2a. When the multilayer film is made of SiO₂/Nb₂O₅, the thickness of each layer may be in a range of 40 nm to 70 nm. The total thickness of the second light reflecting layer 2b may be appropriately set in accordance with a desired reflection band. The total thickness of the second light reflecting layer 2b may be, for example, in a range of 0.08 μm to 3 μm, in a range of 0.3 μm to 2.5 μm, in a range of 0.6 μm to 2.5 μm, or in a range of 1 μm to 2 μm.

Examples of the second light reflecting layer 2b include oxide, nitride, and fluoride of Si, Mg, Al, Hf, Nb, Zr, Sc, Ta, Ga, Zn, Y, B, and Ti, and the like. The second light reflecting layer 2b may be, for example, a dielectric multilayer film in which two kinds selected from SiO₂, Nb₂O₃, Ta₂O₅, and Al₂O₃ are alternately repeated. The combination of dielectrics may be SiO₂/Nb₂O₃, SiO₂/Ta₂O₅, or SiO₂/Al₂O₃.

### Insulating Layer 7

The insulating layer 7 covers a part of an upper surface of the third semiconductor layer portion 6, a lateral surface of the third semiconductor layer portion 6, a lateral surface of the second semiconductor layer portion 5, a lateral surface of the active layer 4, a lateral surface of the first semiconductor layer portion 3, and an upper surface of the first semiconductor layer portion 3. Thus, leakage current from the lateral surface can be reduced, and the VCSEL element L1 can be stably driven. The insulating layer 7 covers at least a part of the upper surface of the first semiconductor layer portion 3, and is provided with an opening at a portion through which the first electrode 8a to be described below is connected. The insulating layer 7 can be made of an inorganic material such as silicon oxide, silicon nitride, silicon oxynitride, tantalum oxide, zirconium oxide, aluminum nitride, aluminum oxide, and germanium oxide. The material constituting the insulating layer 7 preferably has a lower refractive index than the material constituting the layered body. Light can be efficiently confined in the semiconductor layered body 30.

### First Electrode 8a

The first electrode 8a is electrically connected to the first semiconductor layer portion 3. In the VCSEL element L1 of the first embodiment, the first electrode 8a is in contact with the first semiconductor layer portion 3 on the upper surface of the first semiconductor layer portion 3 exposed from the insulating layer 7. As illustrated in FIGS. 1 and 2, the first electrode 8a surrounds the periphery of the second light reflecting layer 2b. In other words, the first electrode 8a surrounds the mesa structure of the first semiconductor layer portion 3. Thus, the bias of current can be efficiently reduced, so that current can be efficiently injected.

### Second Electrode 8b

The second electrode 8b is in contact with the third semiconductor layer portion 6. In the VCSEL element L1 of the first embodiment, the second electrode 8b is in contact with a part of the upper surface of the third semiconductor layer portion 6 exposed from the insulating layer 7 and lateral and upper surfaces of the insulating layer 7. The second electrode 8b overlaps the non-current injection region 50b and does not overlap the current injection region 50a in top view. As illustrated in FIG. 1, on the third semiconductor layer portion 6, the second electrode 8b is an annular electrode surrounding the center of the third semiconductor layer portion 6 and preferably has a circular ring shape. Thus, current can be more uniformly injected into the third semiconductor layer portion 6.

In the VCSEL element L1 of the first embodiment, the second electrode 8b is disposed on the surface of the third semiconductor layer portion 6 exposed from the second light reflecting layer 2b and between the third semiconductor layer portion 6 and the second light reflecting layer 2b. Thus, the second electrode 8b can be brought close to the current injection region 50a to efficiently inject current. In addition, since the third semiconductor layer portion 6 includes a relatively large amount of impurities, current is likely to flow in an in-plane direction. With the second electrode 8b having the above configuration, the path of current that flows into a plane of the third semiconductor layer portion 6 is shortened by the length of an overlap with the second light reflecting layer 2b in top view as compared with when the second electrode 8b is provided only on the surface of the third semiconductor layer portion 6 exposed from the second light reflecting layer 2b. Accordingly, current can be further spread into the plane of the third semiconductor layer portion 6 from the shortened current path, so that current can be efficiently injected into the current injection region 50a.

As illustrated in FIG. 3, in the VCSEL element L1, the second electrode 8b and the current injection region 50a do not overlap each other and are separated from each other by the shortest distance w in the X direction. In cross-sectional view perpendicular to the upper surface of the third semiconductor layer portion 6, the shortest distance w between an end of the second electrode 8b and an end of the current injection region 50a in a direction parallel to the upper surface of the third semiconductor layer portion 6 is in a range of 1 μm to 10 μm. With this structure, the second electrode 8b is located closer to the current injection region 50a, and thus current can be efficiently injected into the third semiconductor layer portion 6. In addition, since a contact area with the third semiconductor layer portion 6 is increased, contact resistance with the third semiconductor layer portion 6 is reduced. In a cross-sectional view perpendicular to the upper surface of the third semiconductor layer portion 6, the shortest distance w between the end of the second electrode 8b and the end of the current injection region 50a in a direction perpendicular to the normal direction of the upper surface of the third semiconductor layer portion 6 is preferably in a range of 5 μm to 10 μm. Thus, the absorption of light by the second electrode 8b can be reduced while reducing a distance for spreading current in a lateral direction.

The first electrode 8a and the second electrode 8b may be made of any conductive material normally used as an electrode in the art. Examples of the conductive material include Ti/Pt/Au and Ti/Rh/Au.

### Second Embodiment

A VCSEL element L2 of the second embodiment is different from the VCSEL element L1 of the first embodiment in the following points. That is, the VCSEL element L2 of the second embodiment is different from the VCSEL element L1 of the first embodiment in that the third semiconductor layer portion 6 includes a first layer 6a that is in contact with the second semiconductor layer portion 5 and includes a third impurity at a first concentration and a second layer 6b that is disposed on the first layer 6a and includes the third impurity at a second concentration lower than the first concentration, and the sum of thicknesses of the first layer 6a and the second layer 6b is 10 nm or more and less than 100 nm. The other configurations are similar to those of the VCSEL element L1 of the first embodiment.

Thus, the VCSEL element L2 has an improved drive time.

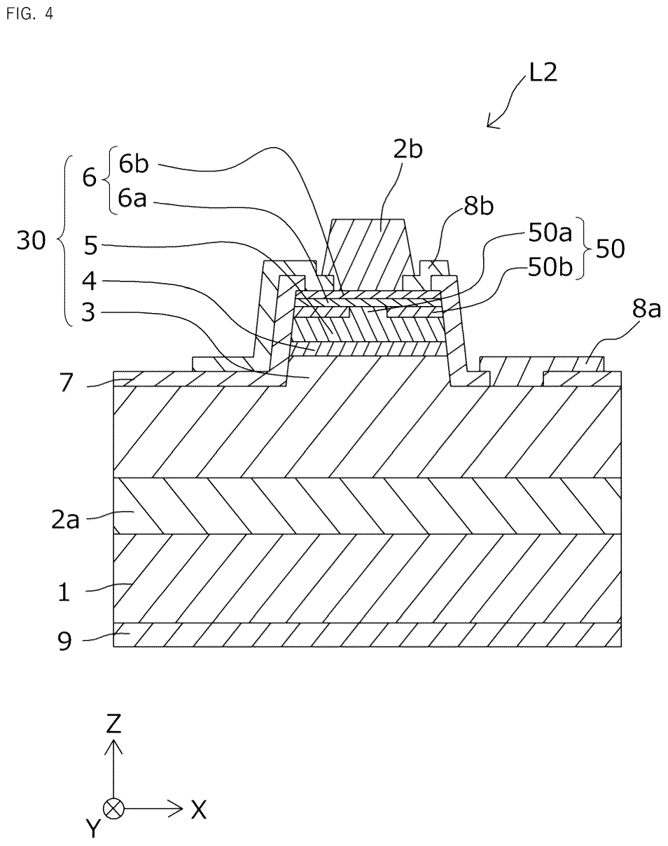

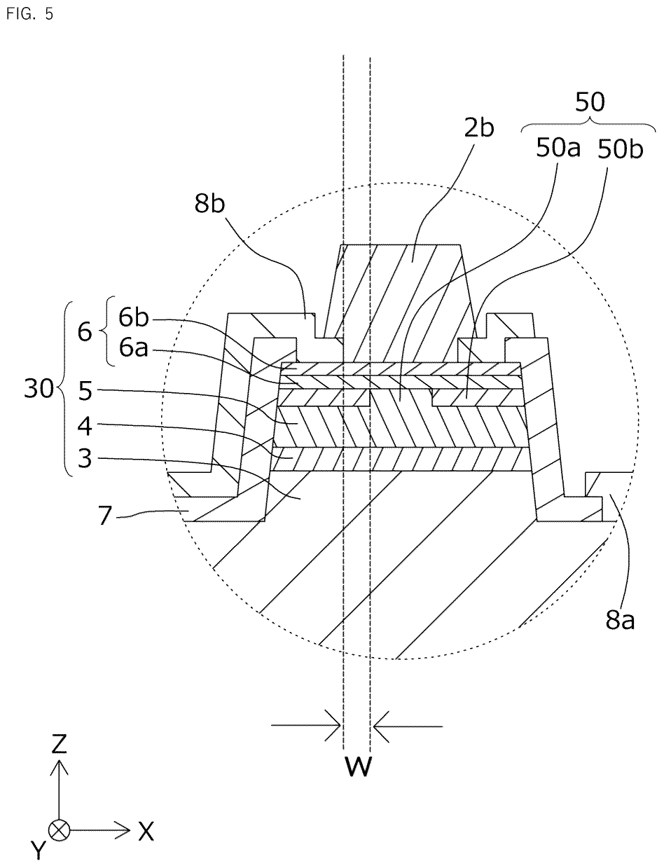

The VCSEL element L2 of the second embodiment is described with reference to FIGS. 4 and 5. FIG. 4 is a schematic cross-sectional view of the VCSEL element L2. The direction of a cross section is the same as that in FIG. 2. FIG. 5 is a schematic enlarged view of the vicinity of a p-side semiconductor layer portion in FIG. 4.

### First Layer 6a

The third semiconductor layer portion 6 includes the first layer 6a. The first layer 6a is in contact with the second semiconductor layer portion 5. The first layer 6a includes the third impurity at the first concentration. The third impurity may be Si or Ge, and is preferably Ge. With this structure, the first layer 6a can be made relatively flat even though the first layer 6a includes the third impurity at a high concentration. The first concentration is preferably in a range of 1×10²⁰ cm⁻³ to 1×10²² cm⁻³, preferably in a range of 2×10²⁰ cm⁻³ to 1×10²¹ cm⁻³, for example. With this concentration, the width of the depletion layer formed by the tunnel junction can be narrowed and a forward voltage can be reduced. The thickness of the first layer 6a may be in a range of 10 nm to 50 nm, in a range of 10 nm to 30 nm, or in a range of 15 nm to 30 nm. The absorption loss due to the first layer 6a is reduced by making the first layer 6a having a relatively high concentration of the third impurity relatively thin. Thus, a threshold current density can be reduced.

### Second Layer 6b

The VCSEL element L2 of the second embodiment includes the second layer 6b in addition to the first layer 6a. As illustrated in FIGS. 4 and 5, the second layer 6b is in contact with the second light reflecting layer 2b and is in contact with the second electrode 8b. The second layer 6b includes the third impurity at the second concentration lower than the first concentration. The third impurity may be Si or Ge, and is preferably Ge. The second concentration may be, for example, in a range of 2×10¹⁹ cm⁻³ to 1×10²¹ cm⁻³ or in a range of 5×10¹⁹ cm⁻³ to 1×10²⁰ cm⁻³. The thickness of the second layer 6b may be larger than 0 nm and 60 nm or less or larger than 0 nm and 50 nm or less. The thickness of the second layer 6b may be preferably larger than 0 nm and 30 nm or less or larger than 0 nm and 20 nm or less. Thus, the absorption loss due to the second layer 6b is reduced as compared with when the thickness of the second layer 6b is larger than 30 nm. Thus, a threshold current density can be reduced.

The sum of the thicknesses of the first layer 6a and the second layer 6b is 10 nm or more and less than 100 nm. Thus, as compared with a case in which the sum of the thicknesses of the first layer 6a and the second layer 6b is 100 nm or more, light absorption can be reduced while spreading current in a plane. The sum of the thicknesses of the first layer 6a and the second layer 6b may be 10 nm or more and less than 60 nm or 10 nm or more and 30 nm. Thus, the light absorption due to the first layer 6a and the second layer 6b is further reduced as compared with a case in which the sum of these thicknesses is 60 nm or more.

### Third Embodiment

A VCSEL element L3 of the third embodiment is different from the VCSEL element L1 of the first embodiment in the following points. That is, the VCSEL element L3 of the third embodiment is different from the VCSEL element L1 of the first embodiment in that the first semiconductor layer portion 3 is formed on the substrate 1 and the first light reflecting layer 2a is disposed on the surface of the substrate 1 opposite to the surface on which the first semiconductor layer portion 3 is formed. The other configurations are similar to those of the VCSEL element L1 of the first embodiment.

This results in the VCSEL element L3 with an improved drive time.

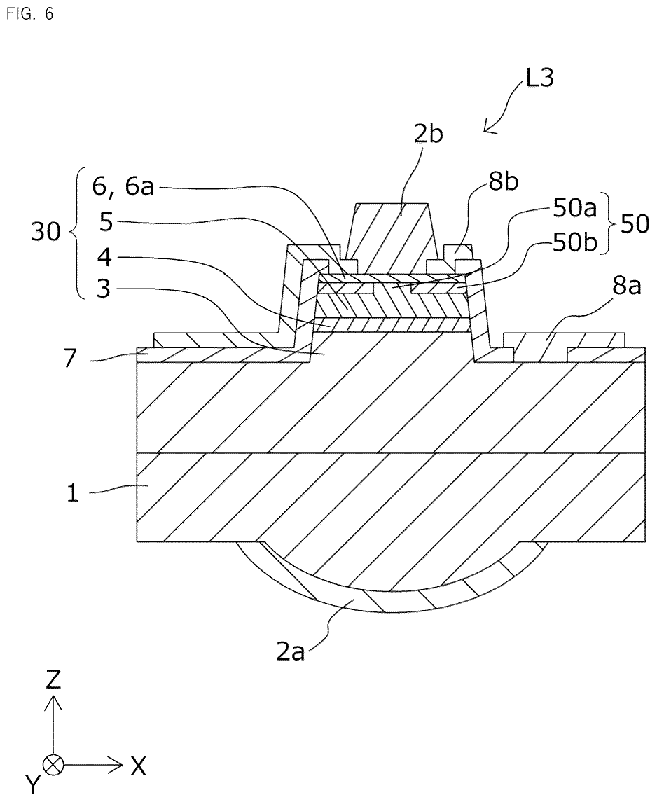

The VCSEL element L3 of the third embodiment is described with reference to FIG. 6. FIG. 6 is a schematic cross-sectional view of the VCSEL element L3. The direction of a cross section is the same as that in FIG. 2.

In the VCSEL element L3 of the third embodiment, the positions of the substrate 1 and the first light reflecting layer 2a are switched relative to those in the VCSEL of the first embodiment. That is, the substrate 1 is disposed between the first light reflecting layer 2a and the first semiconductor layer portion 3. This allows the first light reflecting layer 2a made of a dielectric multilayer film to be formed. A desired reflectance is easily obtained by arbitrarily setting the difference in refractive index between materials constituting the dielectric multilayer film.

In the VCSEL element L3, the lower surface of the substrate 1 immediately below the second light reflecting layer 2b has a concave shape. The first light reflecting layer 2a is a dielectric multilayer film formed along the concave shape of the substrate 1. Thus, the first light reflecting layer 2a can be used as a concave mirror. By condensing light on the active layer 4 by the concave mirror, the diffraction loss caused while light travels back and forth between resonators is reduced, and laser light can be efficiently generated. By setting the curvature radius of the concave portion such that the beam waist of laser light condensed by the first light reflecting layer 2a is located in the vicinity of the active layer 4 or the second light reflecting layer 2b, light amplification efficiency is improved. In addition, the resonator length of the VCSEL element L3 may be made longer than those of the VCSEL elements of the first and second embodiments because the diffraction loss is reduced by the concave shape of the substrate. The resonator length may be, for example, larger than 20 times and 50 times or less or larger than 20 times and 30 times or less λ/(2×n_{eq}).

The VCSEL element L3 of the third embodiment may be modified based on the description of the second embodiment. That is, the third semiconductor layer portion 6 may include the first layer 6a and the second layer 6b.

### Fourth Embodiment

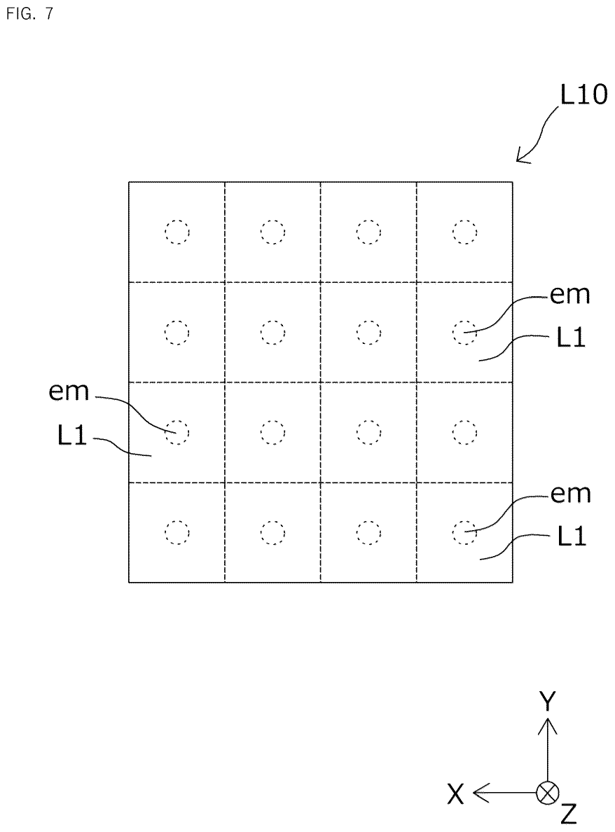

FIG. 7 illustrates a plan view of a vertical cavity surface emitting laser array L10 (hereinafter, simply referred to as a VCSEL array L10) of the fourth embodiment. FIG. 7 is a plan view viewed from the substrate 1 side. The VCSEL array L10 includes a plurality of VCSEL elements L1, L2, or L3. FIG. 7 illustrates the VCSEL element L1 as an example. As illustrated in FIG. 7, in the VCSEL array L10, the plurality of VCSEL elements L1 are arranged in a matrix of m rows and n columns (m is an integer of 2 or more and n is an integer of 1 or more), and each of the VCSEL elements L1 includes a light-emitting region em. In FIG. 7, each of regions separated by broken lines is a region of the VCSEL element L1, and the light-emitting region em is a region surrounded by a dotted circle. In the VCSEL array L10, by causing the VCSEL elements L1 to emit light individually or simultaneously, integration or density of laser light can be improved as compared with when one of the VCSEL elements L1 is caused to emit light alone.

The VCSEL elements L1, L2, and L3 and the VCSEL array L10 can be used for various applications. These can be used for various applications such as communication, display, optical interconnect, sensing, and wearable terminals.

### First Example (Ex. 1)

As a VCSEL element of the first example, the VCSEL element described in the first embodiment was manufactured. In the VCSEL element of the first example, a first light reflecting layer, a first semiconductor layer portion, an active layer, a second semiconductor layer portion, a first layer serving as a third semiconductor layer portion, and a second light reflecting layer were sequentially formed on a GaN substrate. The first light reflecting layer was a semiconductor multilayer film made of AlInN and GaN, and the second light reflecting layer 2b was a dielectric multilayer film made of a combination of silicon oxide and niobium oxide. The first layer was made of a GaN layer, and was formed under conditions that the GaN layer includes Ge as the third impurity at a concentration higher than 2.4×10²⁰ cm⁻³. The first layer was formed under conditions such that the thickness is 20 nm.

### Second Example (Ex. 2)

As a VCSEL element of the second example, the VCSEL element described in the second embodiment was manufactured. The VCSEL element of the second example is different from the VCSEL element of the first example in that a second layer is formed in addition to the first layer, as the third semiconductor layer portion. In the second example, the first layer was made of a GaN layer and was formed under conditions that the GaN layer includes Ge as the third impurity at a concentration higher than 2.4×10²⁰ cm⁻³. The first layer was formed under conditions such that the thickness is 20 nm. The second layer was made of a GaN layer and was formed under conditions that the GaN layer includes Ge as the third impurity at a concentration in a range of 1×10²⁰ cm⁻³ to 2×10²⁰ cm⁻³. The second layer was formed under conditions such that the thickness is 10 nm. The VCSEL element of the second example was formed such that the total thickness of the third semiconductor layer portion (that is, the total thickness of the first layer and the second layer) is 30 nm.

### Third Example (Ex. 3)

A VCSEL element of the third example is different from the VCSEL element of the second example in that the third impurity of the first layer is changed to Si and the thickness of the second layer is changed to 40 nm.

### First Reference Example (Ref. 1)

A VCSEL element of the first reference example is different from the VCSEL elements of the first, second, and third examples in that an ITO having a thickness of 20 nm instead of the third semiconductor layer portion is formed on the second semiconductor layer portion.

### Second Reference Example (Ref. 2)

A VCSEL element of the second reference example is different from the VCSEL elements of the first, second, and third examples in that an ITO having a thickness of 30 nm instead of the third semiconductor layer portion is formed on the second semiconductor layer portion.

In the examples and the reference examples, the same MOCVD apparatus was used to manufacture the VCSEL elements of the first and second examples and the first reference example. In addition, the same MOCVD apparatus was used to manufacture the VCSEL elements of the third example and the second reference example. Evaluation results of the first and second examples and the first reference example, and evaluation results of the third example and the second reference example are separately described below.

### Evaluation

### I-L Characteristics

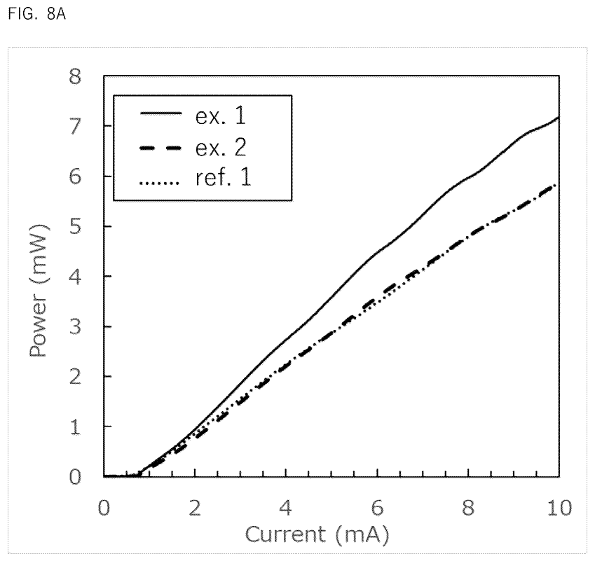

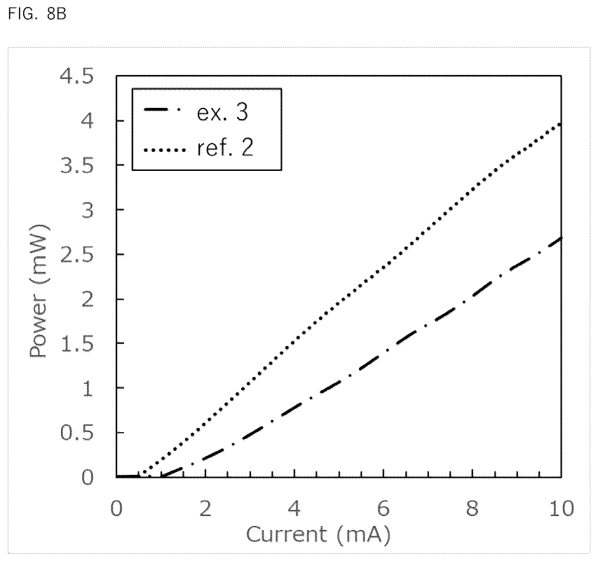

The I-L characteristics were measured for the VCSEL elements of the first example, the second example, the third example, the first reference example, and the second reference example. The results of the I-L measurement were divided into groups according to the manufacturing apparatus of the VCSEL element and compared. FIG. 8A is a graph showing the I-L characteristics of the VCSEL elements of the first example, the second example, and the first reference example. The solid line represents the result of the first example, the broken line represents the result of the second example, and the dotted line represents the result of the first reference example. FIG. 8B is a graph showing the I-L characteristics of the VCSEL elements of the third example and the second reference example. The alternate long and short dash line represents the result of the third example and the dotted line represents the result of the second reference example.

From FIG. 8A, the slope efficiency of the VCSEL element of the first example was higher than that of the VCSEL element of the second example. The initial value of current required for obtaining an output of 1 mW was lower in the VCSEL element of the first example than in the VCSEL element of the second example. This is presumably because the thickness of the third semiconductor layer portion of the VCSEL element of the first example is smaller than the thickness of the third semiconductor layer portion of the VCSEL element of the second example and light absorption of the VCSEL element of the first example is reduced. The VCSEL element of the second example had substantially the same I-L characteristics as the VCSEL element of the first reference example. From FIG. 8B, the initial value of current required for obtaining an output of 1 mW was lower in the second reference example than in the third example.

### Lifespan Characteristics

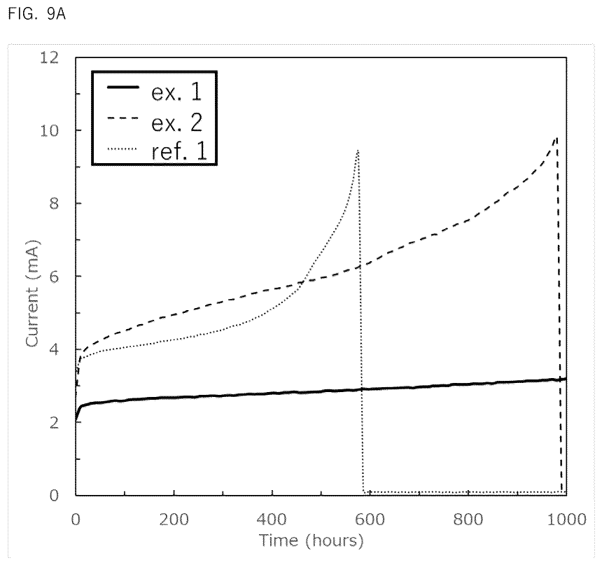

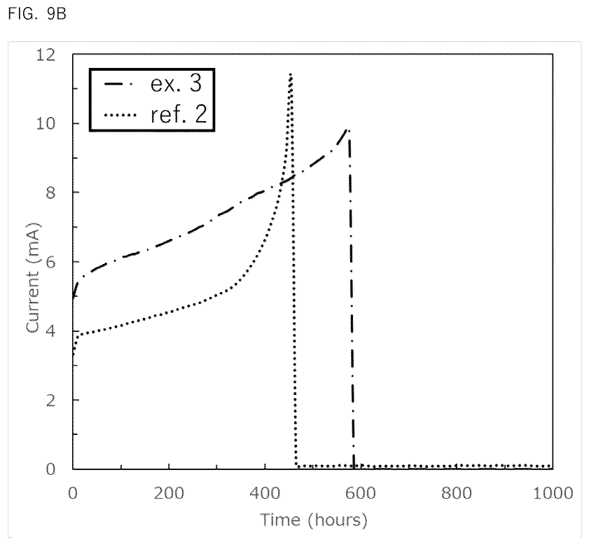

The lifespan characteristics were evaluated for the VCSEL elements of the first example, the second example, the third example, the first reference example, and the second reference example. The lifespan characteristics were measured at a current value at which the output of laser light is 1 mW in an environment of 25° C. FIG. 9A is a graph showing the lifespan characteristics of the VCSEL elements of the first example, the second example, and the first reference example. The solid line represents the result of the first example, the broken line represents the result of the second example, and the dotted line represents the result of the first reference example. FIG. 9B is a graph showing the lifespan characteristics of the VCSEL elements of the third example and the second reference example. The alternate long and short dash line represents the result of the third example and the dotted line represents the result of the second reference example.

The VCSEL elements of the first and second examples provided with the third semiconductor layer portion were able to be continuously driven for a longer time than the VCSEL element of the first reference example not provided with the third semiconductor layer portion. This is presumably because the absorption loss was reduced by the third semiconductor layer portion.

In addition, the VCSEL element of the first example was able to be continuously driven for a longer time than the VCSEL element of the second example. As described with reference to FIG. 8A, the third semiconductor layer portion of the VCSEL element of the first example was thinner than the third semiconductor layer portion of the VCSEL element of the second example, and the initial value of current required for obtaining an output of 1 mW was lower in the VCSEL element of the first example than in the VCSEL element of the second example. This presumably reduced degradation due to long-time current injection, allowing long-time continuous driving.

Continuous driving of the VCSEL element of the first example was stopped after 1000 hours, but the behavior of the current value required for maintaining an output of 1 mW was stable. For example, the slope of the graph between 900 hours and 1000 hours in the first example was smaller than the slopes of the graph between 100 hours and 200 hours in the second example and the first reference example, and it was expected that the VCSEL element of the first example was stably driven. This result suggests that the VCSEL element of the first example can be continuously driven for a long time exceeding 1000 hours.

The VCSEL element of the third example provided with the third semiconductor layer portion was able to be continuously driven for a longer time than the VCSEL element of the second reference example not provided with the third semiconductor layer portion. In addition, as shown in FIG. 9B, the VCSEL element of the third example was able to be continuously driven for a longer time than the VCSEL element of the second reference example. As described with reference to FIG. 8B, the third semiconductor layer portion of the VCSEL element of the third example was thicker than ITO of the VCSEL element of the second reference example, and the value of current required for obtaining an output of 1 mW was also larger in the VCSEL element of the third example than in the VCSEL element of the second reference example. Nevertheless, as shown in FIG. 9B, continuous driving for a longer time was able to be performed in the third example than in the second reference example. This is presumably because GaN of the third semiconductor layer portion is made of single crystal while the ITO is made of polycrystal, the crystallinity of GaN is higher than the crystallinity of ITO, and the loss and resistance due to the grain boundary of GaN are smaller than those of ITO.

What is claimed is:

1. A vertical cavity surface emitting laser element comprising:
a first light reflecting layer;
a first semiconductor layer portion disposed on the first light reflecting layer and containing a first impurity of a first conductivity type;
a second semiconductor layer portion containing a second impurity of a second conductivity type;
an active layer disposed between the first semiconductor layer portion and the second semiconductor layer portion;
a third semiconductor layer portion disposed on the second semiconductor layer portion, containing a third impurity of the first conductivity type at a higher concentration than a concentration of the first impurity in the first semiconductor layer portion, and having a thickness of 10 nm or more and less than 100 nm;
a second light reflecting layer disposed on the third semiconductor layer portion;
a first electrode electrically connected to the first semiconductor layer portion; and
a second electrode in contact with the third semiconductor layer portion.

2. The vertical cavity surface emitting laser element according to claim 1, wherein
the third semiconductor layer portion includes a first layer in contact with the second semiconductor layer portion and the second electrode, and
a thickness of the first layer is 10 nm or more and less than 30 nm.

3. The vertical cavity surface emitting laser element according to claim 1, wherein
the third semiconductor layer portion includes
a first layer in contact with the second semiconductor layer portion, the first layer containing the third impurity at a first concentration, and
a second layer that is disposed on the first layer, the second layer containing the third impurity at a second concentration lower than the first concentration, and
a sum of a thickness of the first layer and a thickness of the second layer is 10 nm or more and less than 100 nm.

4. The vertical cavity surface emitting laser element according to claim 3, wherein the thickness of the first layer is in a range of 10 nm to 30 nm.

5. The vertical cavity surface emitting laser element according to claim 3, wherein the thickness of the second layer is larger than 0 nm and 30 nm or less.

6. The vertical cavity surface emitting laser element according to claim 4, wherein the thickness of the second layer is larger than 0 nm and 30 nm or less.

7. The vertical cavity surface emitting laser element according to claim 1, wherein a concentration of the third impurity contained in the third semiconductor layer portion is in a range of 2×10¹⁹ cm⁻³ to 1×10²² cm⁻³.

8. The vertical cavity surface emitting laser element according to claim 2, wherein a concentration of the third impurity contained in the third semiconductor layer portion is in a range of 2×10¹⁹ cm⁻³ to 1×10²² cm⁻³.

9. The vertical cavity surface emitting laser element according to claim 3, wherein a concentration of the third impurity contained in the third semiconductor layer portion is in a range of 2×10¹⁹ cm⁻³ to 1×10²² cm⁻³.

10. The vertical cavity surface emitting laser element according to claim 1, wherein the third impurity is germanium.

11. The vertical cavity surface emitting laser element according to claim 1, wherein
the second semiconductor layer portion includes a current injection region, and
a non-current injection region is provided to surround a periphery of the current injection region in a top view.

12. The vertical cavity surface emitting laser element according to claim 2, wherein
the second semiconductor layer portion includes a current injection region, and
a non-current injection region is provided to surround a periphery of the current injection region in a top view.

13. The vertical cavity surface emitting laser element according to claim 11, wherein the non-current injection region includes an oxide layer containing gallium and located on a part of a surface of the second semiconductor layer portion, and
the oxide layer contains aluminum at least in a part of the oxide layer.

14. The vertical cavity surface emitting laser element according to claim 12, wherein
the non-current injection region includes an oxide layer containing gallium and located at a part of a surface of the second semiconductor layer portion, and
the oxide layer contains aluminum at least in a part of the oxide layer.

15. The vertical cavity surface emitting laser element according to claim 14, wherein in a cross-sectional view perpendicular to an upper surface of the third semiconductor layer portion, a shortest distance between an end of the second electrode and an end of the current injection region in a direction parallel to the upper surface of the third semiconductor layer portion is in a range of 1 μm to 10 μm.

16. The vertical cavity surface emitting laser element according to claim 11, wherein a thickness of the non-current injection region is in a range of 0.1 nm to 10 nm.

17. The vertical cavity surface emitting laser element according to claim 1, wherein an arithmetic mean height Sa of a surface of the third semiconductor layer portion is in a range of 0.1 nm to 2 nm.

18. The vertical cavity surface emitting laser element according to claim 11, wherein
an arithmetic mean height Sa of a part of a surface of the third semiconductor layer portion immediately above the current injection region is in a range of 0.1 nm to 1 nm, and
an arithmetic mean height Sa of a part of the surface of the third semiconductor layer portion immediately above the non-current injection region is in a range of 0.1 nm to 1 nm.

19. The vertical cavity surface emitting laser element according to claim 1, wherein the second electrode is disposed on a surface of the third semiconductor layer portion exposed from the second light reflecting layer and between the third semiconductor layer portion and the second light reflecting layer.

20. The vertical cavity surface emitting laser element according to claim 1, wherein a material of the first semiconductor layer portion, the second semiconductor layer portion, and the third semiconductor layer portion is a nitride semiconductor.
